(19) United States
(12) Patent Application Publication
(10) Pub. No.: US 2023/0074287 A1
(43) Pub. Date: Mar. 9, 2023

(54) ELECTRONIC COMPONENT AND DOUBLE-SIDED TAPE FOR ATTACHING ELECTRONIC COMPONENT

(71) Applicant: Murata Manufacturing Co., Ltd., Nagaokakyo-shi (JP)

(72) Inventors: Shingo HARADA, Nagaokakyo-shi (JP); Yoshihiko NISHIZAWA, Nagaokakyo-shi (JP)

(21) Appl. No.: 18/055,480

(22) Filed: Nov. 15, 2022

Related U.S. Application Data
(63) Continuation of application No. PCT/JP2022/016194, filed on Mar. 30, 2022.

(30) Foreign Application Priority Data
Jun. 15, 2021 (JP) 2021-099167

(51) Int. Cl. H05K 5/02; C09J 7/00

(52) U.S. Cl. CPC H05K 5/0217; C09J 7/00; C09J 2203/326; C09J 2301/124

(57) ABSTRACT

An electronic device that includes: a housing; an electronic component; and a double-sided tape interposed between the housing and the electronic component and attaching the electronic component to the housing, wherein the double-sided tape has at least one cut extending from an outer peripheral edge to an inner portion of the double-sided tape in a plan view of the double-sided tape.

### CROSS REFERENCE TO RELATED APPLICATIONS

The present application is a continuation of International application No. PCT/JP2022/016194, filed Mar. 30, 2022, which claims priority to Japanese Patent Application No. 2021-099167, filed Jun. 15, 2021, the entire contents of each of which are incorporated herein by reference.

### FIELD OF THE INVENTION

An embodiment of the present invention relates to an electronic component attached to an electronic device.

### BACKGROUND OF THE INVENTION

Patent Document 1 discloses a touch type input device as an example of an electronic component attached to an electronic device. An electronic component such as that disclosed in Patent Document 1 is attached to a housing of an electronic device with a double-sided tape interposed therebetween.
Patent Document 1: WO2016/035682A

### SUMMARY OF THE INVENTION

In a case where the electronic component is attached with the double-sided tape, if there is defective attaching of the double-sided tape, the electronic component may be detached from the electronic device. Therefore, at the time of shipment of the electronic component, a separator for protecting an adhesive surface is attached to the double-sided tape. The separator is attached to a principal surface of the double-sided tape on the side on which the double-sided tape is attached to the housing. The separator protects the adhesive surface and is excellent in releasability. A user peels off the separator from the double-sided tape, and attaches the adhesive surface of the double-sided tape to the electronic device.

However, in the separator having excellent releasability, a very strong force is required at the time of peeling off due to surface tension generated between the double-sided tape and the separator. For this reason, when the user tries to peel off only the separator, not only the separator but also the double-sided tape may be peeled off from the electronic component.

Therefore, an object of an embodiment of the present invention is to provide an electronic component that prevents a double-sided tape from being peeled off when a separator is peeled off.

An electronic device according to an embodiment of the present invention includes a housing; an electronic component; and a double-sided tape interposed between the housing and the electronic component and attaching the electronic component to the housing, wherein the double-sided tape has at least one cut extending from an outer peripheral edge to an inner portion of the double-sided tape in a plan view of the double-sided tape.

According to the electronic component of the present embodiment, when a separator is peeled off, air enters the cut, and surface tension is reduced. Therefore, the electronic component of the present embodiment can prevent the double-sided tape from being peeled off when the separator is peeled off.

According to an embodiment of the present invention, a double-sided tape can be prevented from being peeled off when a separator is peeled off.

### BRIEF EXPLANATION OF THE DRAWINGS

FIG. 1 is a perspective view of an electronic device 100 including a deformation detection sensor 10.

FIG. 2(A) is a sectional view of a YZ plane, and FIG. 2(B) is a sectional view of an XZ plane.

FIG. 3 is a plan view of the deformation detection sensor 10 and a double-sided tape 11.

FIG. 4 is a plan view illustrating the deformation detection sensor 10, the double-sided tape 11, and a separator 90 at the time of shipment.

FIG. 5(A) is a schematic sectional view illustrating the deformation detection sensor 10, the double-sided tape 11, and the separator 90 at the time of shipment, and FIGS. 5(B) and 5(C) are schematic sectional views at the start of peeling off the separator 90.

FIG. 6(A) is a graph illustrating a peeling strength when the separator 90 of the present embodiment is peeled off, and FIG. 6(B) is a graph illustrating a peeling strength at the time of peeling off the separator 90 in a case where there is no cut in the double-sided tape as a reference example.

FIG. 7 is a plan view of an example in which a cut 51 is provided at a corner.

FIG. 8 is a plan view of an example including a plurality of cuts 51A and 51B.

FIGS. 9(A) and 9(B) are sectional views of a double-sided tape 11 having a plurality of adhesive layers.

### DETAILED DESCRIPTION OF THE INVENTION

Hereinafter, a deformation detection sensor 10 as an example of an electronic component of the present invention and an electronic device 100 including the deformation detection sensor 10 will be described with reference to the drawings. Note that, in each drawing, electrodes, wires, and the like are omitted for ease of description.

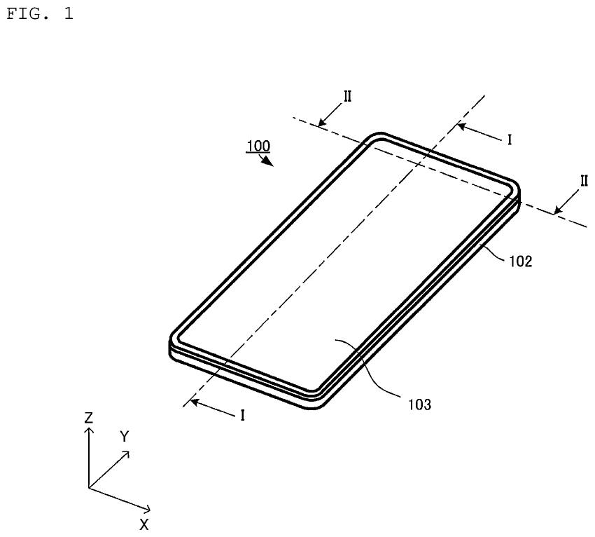

FIG. 1 is a perspective view of the electronic device 100 including the deformation detection sensor 10. The electronic device 100 is an information processing device such as a smartphone.

As illustrated in FIG. 1, the electronic device 100 includes a housing 102 having a substantially rectangular parallelepiped shape. The electronic device 100 includes a flat surface panel 103 disposed in the housing 102. The surface panel 103 functions as an operation surface on which a user performs a touch operation using a finger, a pen, or the like. Hereinafter, a description will be given assuming that a width direction (horizontal direction) of the housing 102 is an X direction, a length direction (vertical direction) is a Y direction, and a thickness direction is a Z direction.

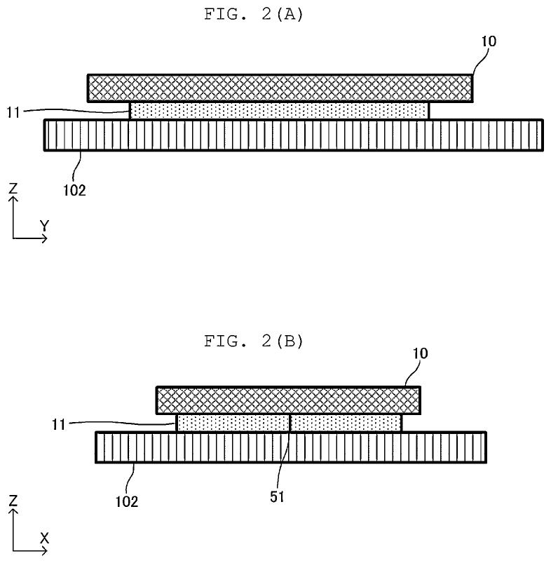

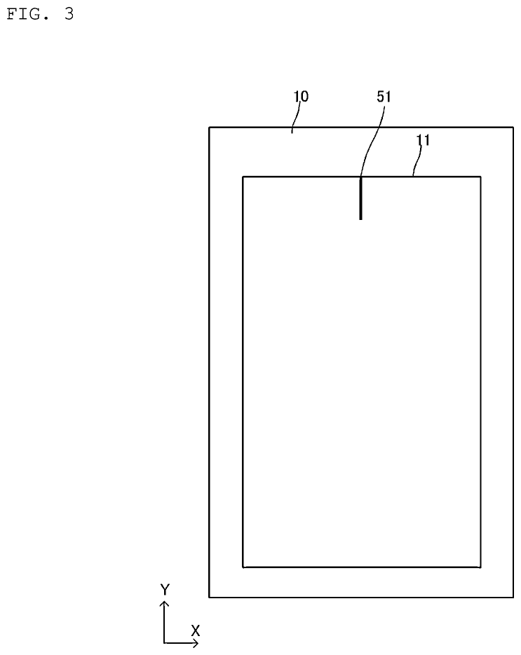

FIG. 2(A) is a sectional view of a YZ plane (a sectional view taken along the line I-I illustrated in FIG. 1), and FIG. 2(B) is a sectional view of an XZ plane (a sectional view taken along the line II-II illustrated in FIG. 1). FIG. 3 is a plan view of the deformation detection sensor 10 and a double-sided tape 11. Note that the sectional view displays a thickness larger than that of an actual component for the sake of explanation.

The deformation detection sensor 10 is attached to the housing 102 of the electronic device 100 with the double-sided tape 11 interposed therebetween. The deformation detection sensor 10 is attached to, for example, a surface inside the housing 102 on the side of the surface panel 103.

The deformation detection sensor 10 is, for example, a piezoelectric sensor including a piezoelectric film. The piezoelectric film of the deformation detection sensor 10 is formed in a rectangular shape in plan view. The piezoelectric film includes, for example, a chiral polymer such as polyvinylidene fluoride (PVDF) or polylactic acid. As the polylactic acid (PLA), either poly-L-lactic acid (PLLA) or poly-D-lactic acid (PDLA) may be used. The housing 102 is deflected when a pressing force is applied. The piezoelectric film expands and contracts in a planar direction according to the deflection of the housing 102. The piezoelectric film is polarized by expansion and contraction in the planar direction, and generates a potential difference between a first principal surface and a second principal surface. In addition, in a case where the electronic device 100 is a flexible bendable device, the piezoelectric film generates a potential difference between the first principal surface and the second principal surface when the electronic device 100 is bent.

Note that electrodes not illustrated in the drawings are formed on both the principal surfaces of the piezoelectric film. These electrodes are connected to a voltage detection circuit not illustrated in the drawings. The voltage detection circuit detects a potential difference between the electrodes on both the principal surfaces. A calculator that is connected to the voltage detection circuit and is not illustrated in the drawings detects deformation of the housing 102 according to a potential difference (voltage).

Note that the deformation detection sensor 10 may be attached to the surface panel 103, a display, a touch sensor, or the like. When the deformation detection sensor 10 is attached to the surface panel 103 the deformation detection sensor 10 can detect the presence or absence of pressing against the surface panel 103 and the pressing force. Note that, when the deformation detection sensor 10 is transparent, the deformation detection sensor 10 may be disposed closer to the surface panel 103 than the display.

The double-sided tape 11 has a cut 51 extending inward from an outer peripheral edge in plan view. As illustrated in FIG. 3, in this example, the cut 51 is provided at a center position in the X direction of the side of the outer peripheral edge in the Y direction. In addition, the cut 51 is provided at a position overlapping the deformation detection sensor 10 in plan view. However, an entire portion of the cut 51 does not need to overlap the deformation detection sensor 10 in plan view. For example, when the double-sided tape 11 is located outside the deformation detection sensor 10 in plan view, a part of the cut 51 may exist outside the deformation detection sensor 10.

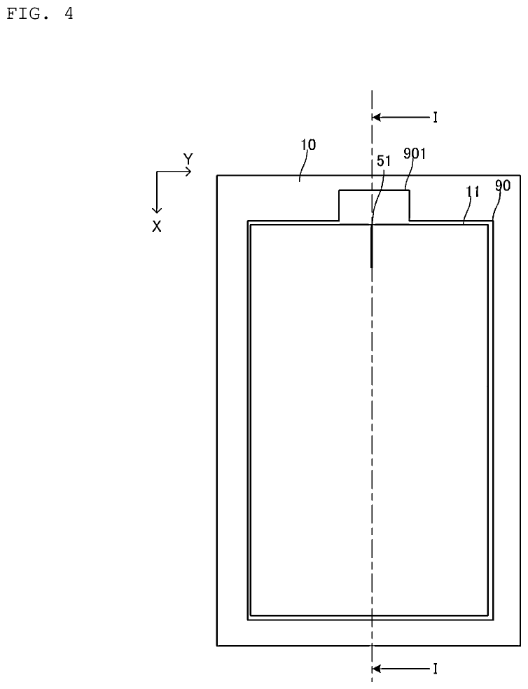

The cut 51 is provided at a peeling start position of a separator 90 attached to a principal surface of the double-sided tape 11 at the time of shipment of the deformation detection sensor 10. See FIG. 4.

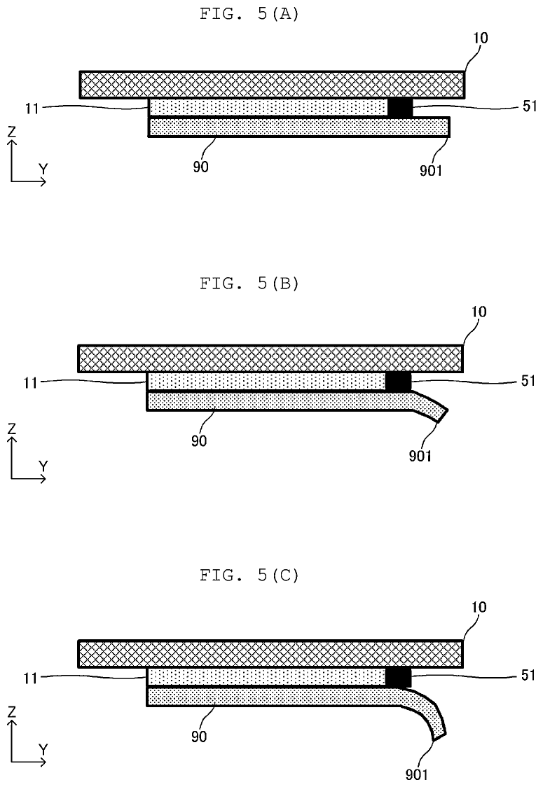

FIG. 4 is a plan view illustrating the deformation detection sensor 10, the double-sided tape 11, and the separator 90 at the time of shipment. FIG. 5(A) is a schematic sectional view (a sectional view taken along the line I-I illustrated in FIG. 4) illustrating the deformation detection sensor 10, the double-sided tape 11, and the separator 90 at the time of shipment.

As illustrated in FIGS. 4 and 5(A), at the time of shipment of the deformation detection sensor 10, the separator 90 is attached to the principal surface of the double-sided tape 11 on the side to be attached to the electronic device 100. The separator 90 protects an adhesive surface of the double-sided tape 11.

The separator 90 has a release portion 901 for peeling off the separator 90. The release portion 901 is a portion of the separator 90 that is not attached to the double-sided tape 11. In this example, as illustrated in FIG. 4, the release portion 901 is provided at a center position in the X direction of the side of the outer peripheral edge in the Y direction. A user of the deformation detection sensor 10 (for example, a manufacturer of the electronic device 100) grips and pulls the release portion 901 with tweezers or the like to peel off the separator 90. That is, the release portion 901 corresponds to the peeling start position of the double-sided tape 11.

FIGS. 5(B) and 5(C) are schematic sectional views at the start of peeling of the separator 90. When the user grips and pulls the release portion 901 with the tweezers or the like to peel off the separator 90, the release portion 901 is pulled toward the side opposite to the deformation detection sensor 10 as illustrated in FIG. 5(B). Therefore, the double-sided tape 11 is pulled in a direction away from the deformation detection sensor 10. At this time, the adhesive force and the surface tension of the double-sided tape 11 are generated on the adhesive surface of the double-sided tape 11 and the separator 90 and the adhesive surface of the double-sided tape 11 and the deformation detection sensor 10.

The double-sided tape 11 of the present embodiment is provided with the cut 51. When the double-sided tape 11 is pulled in a direction away from the deformation detection sensor 10, air enters the cut 51. As a result, the surface tension generated on the adhesive surface of the double-sided tape 11 and the separator 90 is reduced. Therefore, the user can peel off the separator 90 as illustrated in FIG. 5(C) without applying a strong force.

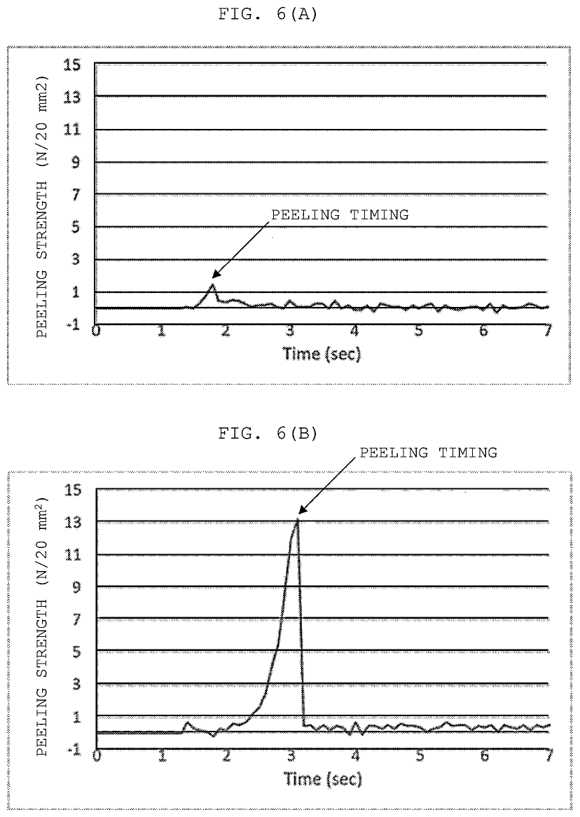

FIG. 6(A) is a graph illustrating a peeling strength when the separator 90 of the present embodiment is peeled off, and FIG. 6(B) is a graph illustrating a peeling strength when the separator 90 is peeled off in a case where there is no cut in the double-sided tape as a reference example. In both the graphs, a vertical axis represents the peeling strength (N/20 mm²), and a horizontal axis represents time (sec). In both FIGS. 6(A) and 6(B), the measurement was performed at room temperature. In both FIGS. 6(A) and 6(B), the elastic modulus of an adhesive layer of the double-sided tape was about several 10 kPa to several 100 kPa at room temperature.

As illustrated in FIG. 6(B), in the reference example, due to an influence of the adhesive force and the surface tension of the double-sided tape, a very strong peeling strength of 13 N/20 mm² or more is required at peeling timing at which the separator is peeled off. Therefore, in the double-sided tape with no cut, when the separator is peeled off, not only the adhesive surface of the double-sided tape and the separator but also the adhesive surface of the double-sided tape and the electronic component may be peeled off.

On the other hand, as illustrated in FIG. 6(A), in the present embodiment, the surface tension is reduced by air entering the cut 51, and the separator 90 can be peeled off with a peeling strength of about 2 N/20 mm² at the peeling timing. Therefore, when the separator 90 is peeled off, it is possible to prevent the adhesive surface of the double-sided tape 11 and the deformation detection sensor 10 from being peeled off.

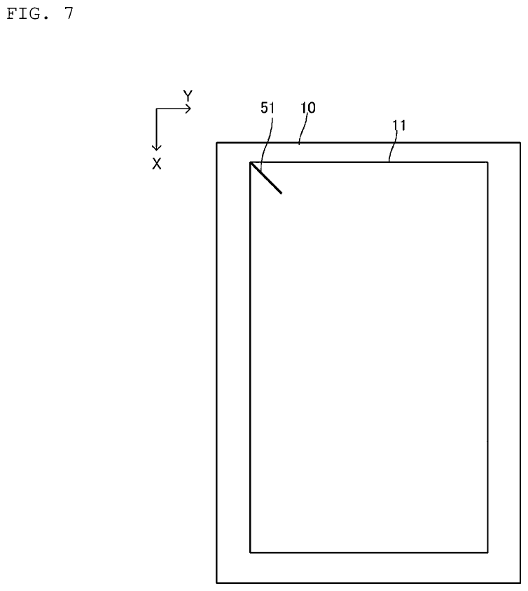

Note that the position of the cut 51 is not limited to the example illustrated in FIG. 3. FIG. 7 is a plan view of an example in which the cut 51 is provided at a corner of the double-sided tape 11. As illustrated in FIG. 7, the cut 51 may be provided at the corner of the double-sided tape 11. In the example of FIG. 4, the release portion 901 of the separator 90 is provided at the center position in the X direction of the side of the outer peripheral edge in the Y direction. However, when the release portion 901 is provided at the corner of the separator 90, it is preferable that the cut 51 is also provided at the corner of the double-sided tape 11. That is, the cut is preferably provided at the peeling start position of the separator attached at the time of shipment of the electronic component.

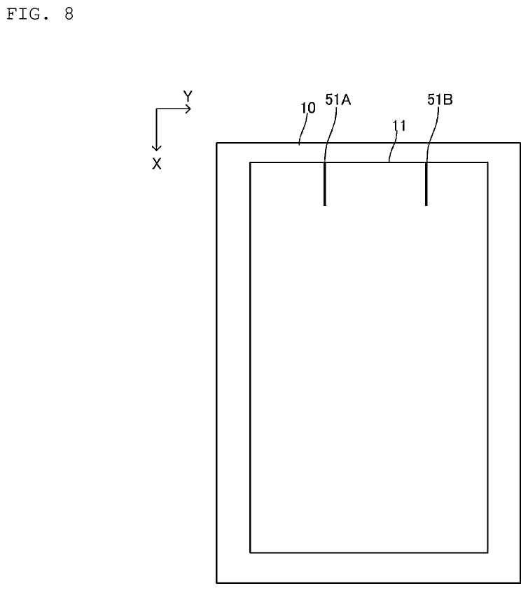

Note that the number of cuts 51 is not limited to one. FIG. 8 is a plan view of an example including a plurality of cuts 51A and 51B. The cut 51A and the cut 51B are provided side by side on the side of the outer peripheral edge in the Y direction. In the example of FIG. 8, since the double-sided tape 11 includes a plurality of cuts, air easily enters when the separator 90 is peeled off, and it is possible to prevent the adhesive surface of the double-sided tape 11 and the deformation detection sensor 10 from being peeled off. In addition, more cuts may be provided.

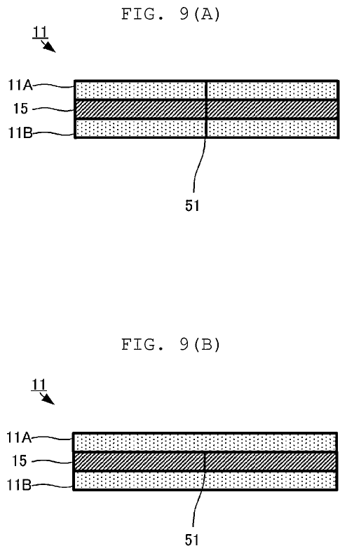

Note that the double-sided tape may include a plurality of adhesive layers. FIGS. 9(A) and 9(B) are sectional views of a double-sided tape 11 having a plurality of adhesive layers. The double-sided tape 11 in this example has a substrate 15, a first adhesive layer 11A attached to a first principal surface of the substrate 15, and a second adhesive layer 11B attached to a second principal surface of the substrate 15. The substrate 15 includes, for example, polyethylene terephthalate (PET).

The cut 51 may be provided over the first adhesive layer 11A, the substrate 15, and the second adhesive layer 11B as illustrated in FIG. 9(A), or may be provided only in the substrate 15 as illustrated in FIG. 9(B).

In a case where the cut 51 is provided only in the substrate 15 as illustrated in FIG. 9(B), air enters from the cut 51 of the substrate 15 when the separator 90 is peeled off, so that it is possible to prevent the adhesive surface of the double-sided tape 11 and the deformation detection sensor 10 from being peeled off.

Note that the cut 51 is provided over the first adhesive layer 11A, the substrate 15, and the second adhesive layer 11B by a cutter or the like at the time of manufacturing. In this case, when a cut width of the cut 51 is small, the adhesive layers are bonded to each other over time in each of the first adhesive layer 11A and the second adhesive layer 11B, and the cut disappears. In this case, the cut is provided only in the substrate 15 as illustrated in FIG. 9(B).

Finally, the description of the embodiments should be considered in all respects as illustrative and not restrictive. The scope of the present invention is defined not by the above-described embodiments but by the claims. Furthermore, the scope of the present invention includes a scope equivalent to the claims.

### DESCRIPTION OF REFERENCE SYMBOLS

10: Deformation detection sensor
11: Double-sided tape
11A: First adhesive layer
11B: Second adhesive layer
15: Substrate
51, 51A, 51B: Cut
90: Separator
100: Electronic device
102: Housing
103: Surface panel
901: Release portion

1. An electronic device comprising:
a housing;
an electronic component; and
a double-sided tape interposed between the housing and the electronic component and attaching the electronic component to the housing, wherein
the double-sided tape has at least one cut extending from an outer peripheral edge to an inner portion of the double-sided tape in a plan view of the double-sided tape.

2. The electronic device according to claim 1, wherein
the double-sided tape has a substrate, a first adhesive layer attached to a first principal surface of the substrate, and a second adhesive layer attached to a second principal surface of the substrate, and
at least the substrate has the at least one cut.

3. The electronic device according to claim 2, wherein the at least one cut extends through the substrate, the first adhesive layer, and the second adhesive layer.

4. The electronic device according to claim 1, wherein the at least one cut is located at a corner of the double-sided tape.

5. The electronic device according to claim 1, wherein the at least one cut is located on a side of the outer peripheral edge of the double-sided tape.

6. The electronic device according to claim 1, wherein the at least one cut is a plurality of cuts.

7. The electronic device according to claim 1, wherein the cut is located at a position overlapping the electronic component in the plan view of the double-sided tape.

8. An electronic component comprising:
a sensor body; and
a double-sided tape attached to a surface of the sensor body, wherein
the double-sided tape has at least one cut extending from an outer peripheral edge to an inner portion of the double-sided tape in a plan view of the double-sided tape.

9. The electronic component according to claim 8, wherein
the double-sided tape has a substrate, a first adhesive layer attached to a first principal surface of the substrate, and a second adhesive layer attached to a second principal surface of the substrate, and
at least the substrate has the at least one cut.

10. The electronic component according to claim 9, wherein the at least one cut extends through the substrate, the first adhesive layer, and the second adhesive layer.

11. The electronic component according to claim 8, wherein the at least one cut is located at a corner of the double-sided tape.

12. The electronic component according to claim 8, wherein the at least one cut is located on a side of the outer peripheral edge of the double-sided tape.

13. The electronic component according to claim 8, wherein the at least one cut is a plurality of cuts.

14. The electronic component according to claim 8, further comprising a separator attached to a principal surface of the double-sided tape such that the double-sided tape is between the sensor body and the separator.

15. The electronic component according to claim 14, wherein the at least one cut is located at a peeling start position of the separator attached to the principal surface of the double-sided tape.

16. The electronic component according to claim 15, wherein the separator includes a release portion that is not attached to the double-sided tape at the peeling start position.

17. The electronic component according to claim 8, wherein the at least one cut is located at a position overlapping the electronic component in the plan view of the double-sided tape.

18. A double-sided tape for attaching an electronic component to a housing of an electronic device, the double-sided tape including at least one cut extending from an outer peripheral edge to an inner portion of the double-sided tape in a plan view of the double-sided tape.

19. The double-sided tape according to claim 18, wherein the double-sided tape includes: a substrate; a first adhesive layer attached to a first principal surface of the substrate; and a second adhesive layer attached to a second principal surface of the substrate, wherein
at least the substrate has the at least one cut.

20. The double-sided tape according to claim 19, wherein the at least one cut extends through the substrate, the first adhesive layer, and the second adhesive layer.
